(19) United States
(12) Patent Application Publication
(10) Pub. No.: US 2008/0258293 A1
(43) Pub. Date: Oct. 23, 2008

(54) SEMICONDUCTOR DEVICE PACKAGE TO IMPROVE FUNCTIONS OF HEAT SINK AND GROUND SHIELD

(75) Inventors: Wen-Kun YANG, Hsin-Chu City (TW); Diann-Fang LIN, Hsinchu County (TW)

Correspondence Address: THE MAXHAM FIRM, 9330 SCRANTON ROAD, SUITE 350, SAN DIEGO, CA, 92121, US

(73) Assignee: ADVANCED CHIP ENGINEERING TECHNOLOGY INC., Hsinchu County (TW)

(21) Appl. No.: 11/736,461

(22) Filed: Apr. 17, 2007

(51) Int. Cl. H01L 23/12; H01L 21/00

(52) U.S. Cl. 257/701; 438/108; 257/E23.003; 257/E21.001

(57) ABSTRACT

The present invention provides a package structure and a method for forming the same. The structure comprises a substrate with contact pads and through holes filled with conducting metals for performing heat dissipation and ground shielding A chip with bonding pads is attached on the contact pad by an adhesive with high thermal conductivity to achieve heat dissipation. A RDL is formed on the substrate and the chip to couple the bonding pad and the contact pad formed on the substrate. The structure of present invention can improve the thickness thereof, and the heat dissipation and ground shielding of the structure are enhanced. Furthermore, the structure can achieve package on package (PoP) structure.

### FIELD OF THE INVENTION

The present invention relates to a structure and a method for semiconductor package, and more particularly to thin semiconductor package.

### DESCRIPTION OF THE PRIOR ART

In the field of semiconductor devices, the device density is increased continuously; therefore reducing the device dimension is demanding. Chip package technique is highly influenced by the development of integrated circuits, therefore, as the size of electronics has became demanding, so does the package technique. For the reasons mentioned above, the trend of package technique is toward ball grid array (BGA), flip chip (FC-BGA), chip scale package (CSP), Wafer level package (WLP) today; wherein, the structure formed by WLP has extremely small dimension and good electrical properties. By utilizing WLP technique, the manufacturing cost and time is reduced and the resulting structure of WLP can be equal to the chip; therefore, this technique can meet the demands of miniaturization of electronic devices.

Though the WLP technique has advantages mentioned above, some issues still exist influencing the acceptance of WLP technique. For instance, some technical involves the usage of chip that directly formed on the upper surface of the substrate and the pads of the semiconductor chip will be redistributed through redistribution processes involving a redistribution layer (RDL) into a plurality of metal pads in an area array type. The build up layer also increases the size of the package. Therefore, the thickness of the package is increased, which conflict with the demand of reducing the size of a chip. The chip is folded in the build up layers; therefore the heat dissipation and ground shielding of the structure are another question needs to be solved.

### SUMMARY OF THE INVENTION

As aforementioned, the present invention provides a package structure with shrinkage size, better heat dissipation and ground shielding to overcome the aforementioned problem.

One aspect of the present invention is to provide a substrate with wiring circuit and through holes filled with metal for connecting pads disposed on opposite side of the substrate.

Another aspect of the present invention is to provide a thinner structure and one of the advantages of the present invention is that an adhesive with higher thermal conductivity is provided.

Further advantage of the present invention is that a metal layer is provided for achieving better thermal dissipation, especially, for high power device, the present invention provides excellent ground shielding for RF or high frequency device. In one embodiment, the present invention includes a metal layer that is employed as an antenna. The present invention offers the scheme of Package on Package to integrate device and shrink the stacking size with simple process.

The present invention provides a package structure comprising a substrate having first contact pad, at least one through hole formed therein. A metal layer is formed at lower surface of the substrate, wherein the at least one through hole connects to the metal layer from the first contact pads for heat dissipation and ground shielding. A chip with a bonding pad is attached on the first contact pads by an adhesive with high thermal conductivity. A dielectric layer is formed on the chip and a second contact pad is formed at upper surface of the substrate. A redistribution layer (RDL) is formed above the chip and coupled the bonding pad to the second contact pad for electrical connection. A solder ball formed on the second contact pad formed on upper surface of the substrate.

The present invention provides a method for manufacturing a package structure, comprising: providing a substrate with a first contact pad, a second contact pad and at least one through hole; dispensing an adhesive on the back side of a chip with a bonding pad; attaching the chip on the first contact pad; forming build up layer to couple the second pad with the boding pad; forming a top protection layer on the chip and the substrate by coating or printing; placing a solder ball on the second contact pad; and reflowing the solder ball whereby forming the solder ball on the second contact pad.

### BRIEF DESCRIPTION OF THE DRAWINGS

FIG. 1 illustrates a package structure discloses in one embodiment of the present invention.

FIG. 2 illustrates a package structure discloses in another embodiment of the present invention.

FIG. 3 illustrates a stacking package structure discloses in another embodiment of the present invention.

FIG. 4 illustrates a package structure disclosed in FIG. 1 disposed on a PCB mother board.

FIG. 5 illustrates a package structure disclosed in FIG. 3 disposed on a PCB mother board.

### DESCRIPTION OF THE PREFERRED EMBODIMENT

The invention will now be described in greater detail with preferred embodiments of the invention and illustrations attached. Nevertheless, it should be recognized that the preferred embodiments of the invention is only for illustrating. Besides the preferred embodiment mentioned here, the present invention can be practiced in a wide range of other embodiments besides those explicitly described, and the scope of the present invention is expressly not limited expect as specified in the accompanying Claims.

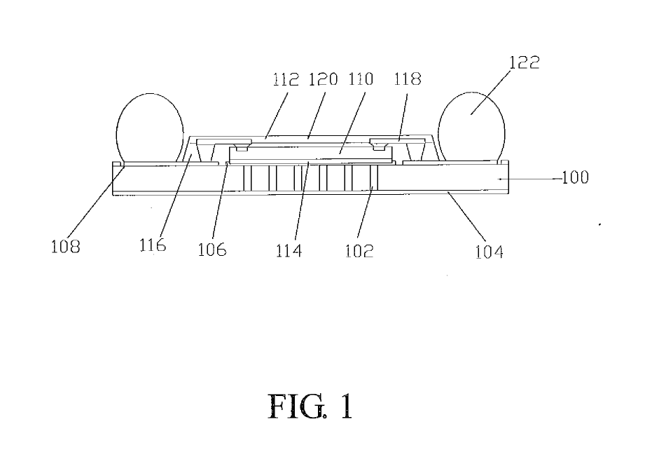

FIG. 1 illustrates a package structure discloses in one embodiment of the present invention. A substrate 100, preferably, made of FR4/FR5/BT or metal/alloy, is provided with through holes 102 formed therein; wherein the through holes 102 are filled with conducting material such as metal, preferably copper material. A conductive layer, for instant metal layer 104, is attached on one surface of the substrate 100 and a conductive (metal) layer 106 is formed on another surface of substrate 100. The through holes 102 is employed to connect the both metal layer 104 and metal layer 106 to achieve the purpose of better thermal dissipation, especially, for high power device. Furthermore, the scheme may provide excellent ground shielding for high power device. Additionally, the metal layer can perform the function as antenna. In another embodiment of the present invention, a material for enhancing heat dissipation is coated on the metal layer 104. Solder metal pads 108 are formed beside the metal layer 106 with a distance between them. Preferably, the thickness of the package structure is approximately 300 um from the layer 104 to the terminal of the solder ball with a thickness of 0.33 mm.

A die 110 with a contact pad 112 formed thereon disposed on the metal layer 106 by an adhesive 114. In one case, the adhesive 114 is provided with good thermal conductivity for dissipating heat generated by the die 110. Preferably, the thickness of the die 110 is in the range of 20-75 um.

A photosensitive dielectric layer 116 is formed over the die 110 and the upper surface of substrate 100. Pluralities of openings are formed within the dielectric layer 116 through the lithography process or exposure and develop procedure. The pluralities of openings are aligned to the contact pads (or I/O pads) 112 and the portion of solder metal pads 108 on the upper surface of the substrate 100, respectively. The RDL (redistribution layer) 118, also referred to as conductive trace 118, is formed on the dielectric layer 116 by removing selected portions of metal layer formed over the layer 116, wherein the RDL 118 keeps electrically connected with the chip 110 through the I/O pads 112 and the solder metal pads 108.

A protection layer 120 is employed to cover the RDL 118, the material of the protection layer 120 includes polyimides (PI) resin compound, silicon rubber based. Solder balls 122 are formed on the solder metal pad 108 for conducting electricity, respectively; wherein the height of the solder balls 122 is about 0.2 mm to 0.35 mm depends on the diameter thereof.

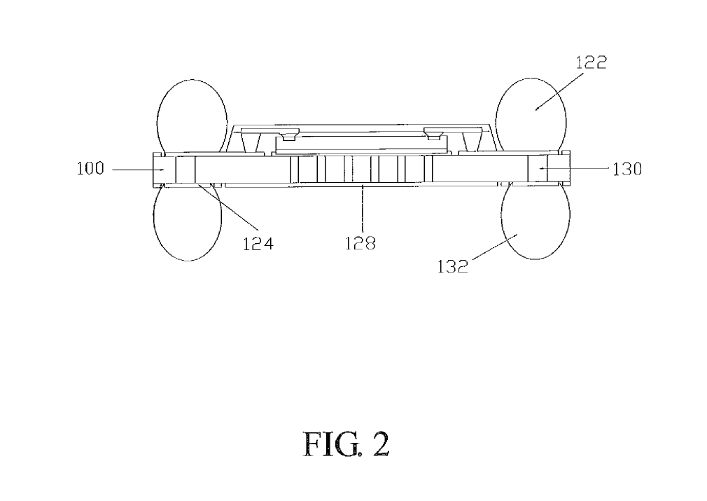

FIG. 2 illustrates another embodiment of the present invention. The structure illustrated in FIG. 2 is quite the same as that embodiment in FIG. 1 except the lower metal layer 104 of FIG. 2 is divided into two major portions including the solder metal pads 124 and a metal layer 128, please refer to FIG. 2. A through hole 130 is formed within the substrate 100 and a conducting material (for example metal or alloy) is filled inside the through holes 130 for keeping electrical connection between the solder metal pads 108 and 124. Further solder balls 132 are formed on the solder metal pads 124 opposite to the solder balls 122, respectively. The scheme may provide stacked structure.

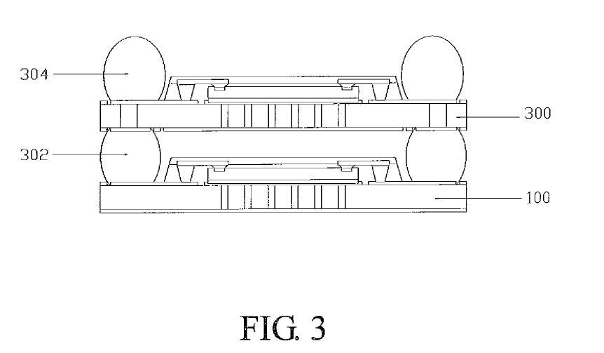

FIG. 3 illustrates a stacked scheme embodiment of the present invention. Referring to the structure illustrated in the FIG. 3, the structure 100 is stacked by the above two structure illustrated in FIG. 1 and 2 with slightly modification. As you may find, the structure shares the solder ball formed there between. And the structure 300 as same as illustrated in FIG. 2 stacks upon the structure 100. Both ends of the solder balls 302 are stage type for keeping electrical connection there between. Solder balls 304 formed on the structure 300 may couple to other component, for example memory device; therefore, a structure referred to as Package on Package (PoP) structure is formed.

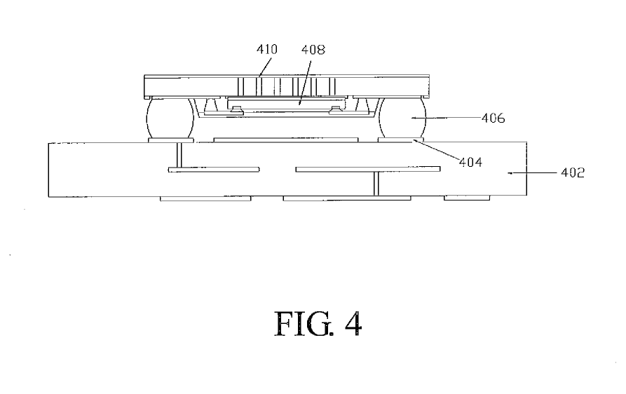

FIG. 4 illustrates a package structure disclosed in FIG. 1 disposed on a PCB mother board. The package structure illustrated in FIG. 1 is disposed on a PCB board 402 with several metal pads 404 formed thereon. The solder balls 406 (stage type) are disposed on the metal pads 402 for keeping electrical connection between the chip 408 and PCB board 402, and the distance between the top of the PCB board 402 and the surface of the metal layer 410 opposite to the chip 408 is about 300 um. Hence, a flip-chip configuration between the substrate 400 and the PCB board 402 is formed. The conductive material of the substrate 400 constructs an electromagnetic (EM) shielding for the chip 408.

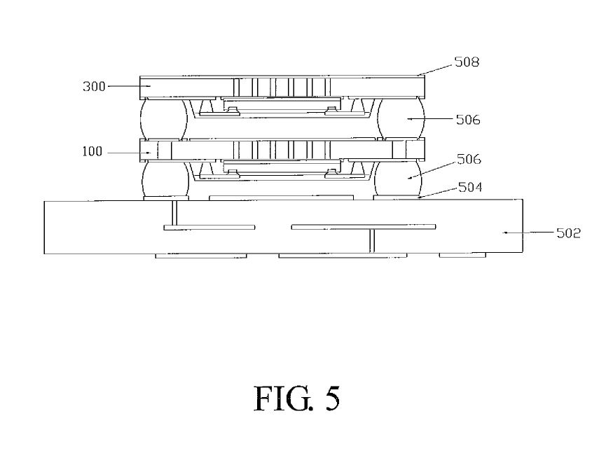

FIG. 5 illustrates a package structure disclosed in FIG. 3 is disposed on a PCB mother board. The package structure illustrated in FIG. 3 is disposed on a PCB board 502 with several metal pads 504 formed thereon. The solder balls 506 (stage type) are disposed on the structure 300 (as shown in FIG. 3) is mounted on the metal pad 504, therefore the PoP structure is disposed on the PCB 502 with upside down configuration. In another embodiment of the present invention, a material for enhancing heat dissipation is coated on the metal layer 508.

The present invention also provides a method for manufacturing a package structure of the present invention. The method provides a substrate (in panel form) with preformed conducting trace and contact pads, and through holes filled with conducting material for keeping electrical connection between a chip and a metal layer that would be disposed on the opposite surface of the substrate in the following step, preferably, the material of the substrate is FR4/FR5/BT or metal/alloy. In another embodiment of the present invention, another through holes with conducting material, for example, metal, filled in and a conducting pad, for example, metal ball pad formed thereon are preformed in the substrate for keeping electrical connection between the conducting metal pads.

Subsequently, an adhesive material (with high thermal conductivity) is dispensed on a substrate and then a pick and place machine is used for attaching the chip on one side of the substrate with adhesive; wherein the thickness of the chip is about 20 to 75 um.

Once the die is redistributed on the substrate (panel base), then, a clean up procedure is performed to clean the dice surface by wet and/or dry clean. Next step is to coat the dielectric materials on the surface of panel. Subsequently, lithography process is performed to open via (contact metal pads) and bonding pads. Plasma clean step is then executed to clean the surface of via holes and bonding pads. Next step is to sputter Ti/Cu as seed metal layers, and then Photo Resistor (PR) is coated over the dielectric layer and seed metal layers for forming the patterns of redistributed metal layers (RDL). Then, the electro plating is processed to form Cu/Au or Cu/Ni/Au as the RDL metal, followed by stripping the PR and metal wet etching to form the RDL metal trace.

Subsequently, the next step is to coat or print the top dielectric layer and to open the contact metal pads. It can repeat the procedures to form multi-RDL layers and dielectric layer, such as seed layer, PR, E-plating or strip/etching.

Thereafter, the solder balls are placed on the solder metal contact pads, and then followed by reflowing the solder balls for attaching them on the solder metal contact pads respectively. Then, the next step is to singulate the panel to complete package structure. It is appreciated that the term metal may refer as any conductive material, metal, alloy or conductive compound. In another embodiment of the present invention, the method further comprising stacking another package structure on the package structure to form a PoP structure

Subsequently, the chip and the substrate (package form) are combined by surface mount technology(SMT), followed by attaching the solder balls of the substrate for connecting pads of a PCB, thereby a flip-chip configuration between the substrate and the PCB is formed; wherein the conductive material of the substrate constructs an EM shielding for the chip.

Although preferred embodiments of the present invention have been described, it will be understood by those skilled in the art that the present invention should not be limited to the described preferred embodiments. Rather, various changes and modifications can be made within the spirit and scope of the present invention, as defined by the following Claims.

What is claimed is:

1. A package structure, comprising
a substrate having a first contact pad and a through hole formed therein;
a metal layer formed at a lower surface of said substrate and coupled to said first contact pads via said through hole for heat dissipation and ground shielding;
a die with a bonding pad attached on said first contact pads by an adhesive with high thermal conductivity;
a dielectric layer formed on said die and a second contact pad formed at an upper surface of said substrate;
a redistribution layer (RDL) formed above said die and coupled to said bonding pad for electrical connection; and
a solder ball formed on said second contact pad formed on said upper surface of said substrate.

2. The structure of claim 1, further comprising a protection layer is formed over said RDL.

3. The structure of claim 1, wherein the material of said metal layer includes heat sink material.

4. The structure of claim 1, wherein said metal layer functions as antenna.

5. The structure of claim 1, wherein said second contact pad is formed on said lower surface of said substrate so as to stack another package structure thereby forming a package on package (PoP) structure.

6. The structure of claim 2, wherein the material of said protection layer includes polyimides (PI) resin compound, silicon rubber based.

7. The structure of claim 1, wherein said substrate includes FR4/FR5/BT or metal/alloy.

8. A method for manufacturing a IC Device package structure, comprising providing a substrate with a first contact pad, a second contact pad and a through hole;
dispensing an adhesive on the back side of a die with a bonding pad;
attaching said die on said first contact pad;
forming build up layer to couple said second pad with said boding pad;
forming a top protection layer on said die and said substrate by coating or printing;
placing a solder ball on said second contact pad; and
reflowing said solder ball whereby forming said solder ball on said second contact pad.

9. The method of claim 8, further comprising mounting said die and said substrate, followed by attaching said solder balls of said substrate to connecting pads of a PCB, thereby forming a flip-chip configuration between said substrate and said PCB, wherein said first contact pad of said substrate constructs a EM shielding for said die.

10. The method of claim 8, further comprising stacking another package structure on said package structure thereby forming a PoP structure.

11. The method of claim 8, wherein said substrate includes FR4/FR5/BT or metal/alloy.

12. The method of claim 8, wherein the material of said protection layer includes polyimides (PI) resin compound, silicon rubber based.

13. The method of claim 8, further comprising coating a layer of material for dissipating heat generated from said die.
